(19) United States
(12) Patent Application Publication
(10) Pub. No.: US 2026/0090075 A1
(43) Pub. Date: Mar. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hiroshi KONO, Himeji Hyogo (JP)

(21) Appl. No.: 19/169,370

(22) Filed: Apr. 3, 2025

(30) Foreign Application Priority Data
Sep. 24, 2024 (JP) 2024-164905

(51) Int. Cl. H10D 84/80; H10D 62/10; H10D 62/60; H10D 62/832

(52) U.S. Cl. CPC H10D 84/811; H10D 62/111; H10D 62/60; H10D 62/8325

(57) ABSTRACT

A semiconductor device of embodiments includes a first element region, a second element region, and an intermediate region provided between the first element region and the second element region. A silicon carbide layer in the intermediate region includes a silicon carbide region extending in a first direction and repeatedly arranged with a first period in a second direction perpendicular to the first direction and another silicon carbide region shifted from the silicon carbide region by half the first period, extending in the first direction, and repeatedly arranged with the first period in the second direction.

### CROSS-REFERENCE TO RELATED APPLICATION

This application is based upon and claims the benefit of priority from Japanese Patent Application No. 2024-164905, filed on Sep. 24, 2024, the entire contents of which are incorporated herein by reference.

### FIELD

Embodiments described herein relate generally to a semiconductor device.

### BACKGROUND

There is a bidirectional switching device in which two MOSFETs are connected in reverse. For example, by applying a bidirectional switching device to an inverter circuit, the power loss of the inverter circuit can be reduced. In order to miniaturize the bidirectional switching device, it is conceivable to integrate two MOSFETs into one chip.

### BRIEF DESCRIPTION OF THE DRAWINGS

FIG. 1 is a schematic top view of a semiconductor device according to a first embodiment;

FIG. 2 is an equivalent circuit diagram of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a schematic cross-sectional view of the semiconductor device according to the first embodiment;

FIG. 6 is a schematic cross-sectional view of a semiconductor device according to a modification example of the first embodiment;

FIG. 7 is a schematic cross-sectional view of a semiconductor device according to a modification example of the first embodiment;

FIG. 8 is a schematic cross-sectional view of a semiconductor device according to a second embodiment;

FIG. 9 is a schematic cross-sectional view of a semiconductor device according to a modification example of the second embodiment; and

FIG. 10 is a schematic cross-sectional view of a semiconductor device according to a modification example of the second embodiment.

### DETAILED DESCRIPTION

A semiconductor device of embodiments includes: a first element region; a second element region; and an intermediate region provided between the first element region and the second element region. The first element region includes: a silicon carbide layer having a first face and a second face on a side opposite to the first face and including a first silicon carbide region of a first conductive type in contact with the second face, a second silicon carbide region of the first conductive type provided between the first silicon carbide region and the first face and having a first conductive type impurity concentration lower than a first conductive type impurity concentration in the first silicon carbide region, a plurality of third silicon carbide regions of a second conductive type provided between the first silicon carbide region and the first face, extending in a first direction parallel to the first face, and repeatedly arranged with a first period with the second silicon carbide region interposed therebetween in a second direction parallel to the first face and perpendicular to the first direction, a fourth silicon carbide region of the first conductive type provided between the second silicon carbide region and the first face and in contact with the second silicon carbide region, a fifth silicon carbide region of the second conductive type provided between the third silicon carbide region and the first face and in contact with the third silicon carbide region, and a sixth silicon carbide region of the first conductive type provided between the third silicon carbide region and the first face; a first gate electrode facing the fourth silicon carbide region and the fifth silicon carbide region; a first gate insulating layer provided between the first gate electrode and the fourth silicon carbide region and between the first gate electrode and the fifth silicon carbide region; and a first electrode provided on the first face side of the silicon carbide layer, in contact with the fourth silicon carbide region and the sixth silicon carbide region, and electrically connected to the fifth silicon carbide region. The second element region includes: the silicon carbide layer including the first silicon carbide region, the second silicon carbide region, a plurality of seventh silicon carbide regions of the second conductive type provided between the first silicon carbide region and the first face, extending in the first direction, and repeatedly arranged with the first period with the second silicon carbide region interposed therebetween in the second direction, an eighth silicon carbide region of the first conductive type provided between the second silicon carbide region and the first face and in contact with the second silicon carbide region, a ninth silicon carbide region of the second conductive type provided between the seventh silicon carbide region and the first face and in contact with the seventh silicon carbide region, and a tenth silicon carbide region of the first conductive type provided between the ninth silicon carbide region and the first face; a second gate electrode facing the eighth silicon carbide region and the ninth silicon carbide region; a second gate insulating layer provided between the second gate electrode and the eighth silicon carbide region and between the second gate electrode and the ninth silicon carbide region; and a second electrode provided on the first face side of the silicon carbide layer, in contact with the eighth silicon carbide region and the tenth silicon carbide region, electrically connected to the ninth silicon carbide region, and electrically isolated from the first electrode. The intermediate region includes: the silicon carbide layer including the first silicon carbide region, the second silicon carbide region, the third silicon carbide region, the seventh silicon carbide region, and an eleventh silicon carbide region of the first conductive type provided between the third silicon carbide region and the first face and between the seventh silicon carbide region and the first face. In the intermediate region, an arrangement of the seventh silicon carbide regions in the second direction is shifted by half the first period with respect to an arrangement of the third silicon carbide regions in the second direction.

Hereinafter, embodiments will be described with reference to the diagrams. In the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

In addition, unless otherwise specified in this specification, the “impurity concentration” means a concentration when the impurity concentration of the opposite conductive type is compensated for. That is, the n-type impurity concentration in an n-type silicon carbide region means a concentration obtained by subtracting the concentration of p-type impurities from the concentration of n-type impurities. In addition, the p-type impurity concentration in a p-type silicon carbide region means a concentration obtained by subtracting the concentration of n-type impurities from the concentration of p-type impurities. In addition, unless otherwise specified in this specification, the “impurity concentration in the silicon carbide region” is a maximum impurity concentration in the corresponding silicon carbide region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, distances such as the depth and thickness of the impurity region can be calculated by using, for example, an SIMS or a Scanning Electron Microscope (SEM). In addition, the depth, thickness, and width of an impurity region and a distance such as a gap between impurity regions can be calculated from, for example, a composite image of an SCM image and an atomic force microscope (AFM) image.

### First Embodiment

A semiconductor device according to a first embodiment includes a first element region, a second element region, and an intermediate region provided between the first element region and the second element region. The first element region includes: a silicon carbide layer having a first face and a second face on a side opposite to the first face and including a first silicon carbide region of a first conductive type in contact with the second face, a second silicon carbide region of the first conductive type provided between the first silicon carbide region and the first face and having a first conductive type impurity concentration lower than a first conductive type impurity concentration in the first silicon carbide region, a plurality of third silicon carbide regions of a second conductive type provided between the first silicon carbide region and the first face, extending in a first direction parallel to the first face, and repeatedly arranged with a first period with the second silicon carbide region interposed therebetween in a second direction parallel to the first face and perpendicular to the first direction, a fourth silicon carbide region of the first conductive type provided between the second silicon carbide region and the first face and in contact with the second silicon carbide region, a fifth silicon carbide region of the second conductive type provided between the third silicon carbide region and the first face and in contact with the third silicon carbide region, and a sixth silicon carbide region of the first conductive type provided between the third silicon carbide region and the first face; a first gate electrode facing the fourth silicon carbide region and the fifth silicon carbide region; a first gate insulating layer provided between the first gate electrode and the fourth silicon carbide region and between the first gate electrode and the fifth silicon carbide region; and a first electrode provided on the first face side of the silicon carbide layer, in contact with the fourth silicon carbide region and the sixth silicon carbide region, and electrically connected to the fifth silicon carbide region. The second element region includes: the silicon carbide layer including the first silicon carbide region, the second silicon carbide region, a plurality of seventh silicon carbide regions of the second conductive type provided between the first silicon carbide region and the first face, extending in the first direction, and repeatedly arranged with the first period with the second silicon carbide region interposed therebetween in the second direction, an eighth silicon carbide region of the first conductive type provided between the second silicon carbide region and the first face and in contact with the second silicon carbide region, a ninth silicon carbide region of the second conductive type provided between the seventh silicon carbide region and the first face and in contact with the seventh silicon carbide region, and a tenth silicon carbide region of the first conductive type provided between the ninth silicon carbide region and the first face; a second gate electrode facing the eighth silicon carbide region and the ninth silicon carbide region; a second gate insulating layer provided between the second gate electrode and the eighth silicon carbide region and between the second gate electrode and the ninth silicon carbide region; and a second electrode provided on the first face side of the silicon carbide layer, in contact with the eighth silicon carbide region and the tenth silicon carbide region, electrically connected to the ninth silicon carbide region, and electrically isolated from the first electrode. The intermediate region includes: the silicon carbide layer including the first silicon carbide region, the second silicon carbide region, the third silicon carbide region, the seventh silicon carbide region, and an eleventh silicon carbide region of the first conductive type provided between the third silicon carbide region and the first face and between the seventh silicon carbide region and the first face. In the intermediate region, an arrangement of the seventh silicon carbide regions in the second direction is shifted by half the first period with respect to an arrangement of the third silicon carbide regions in the second direction.

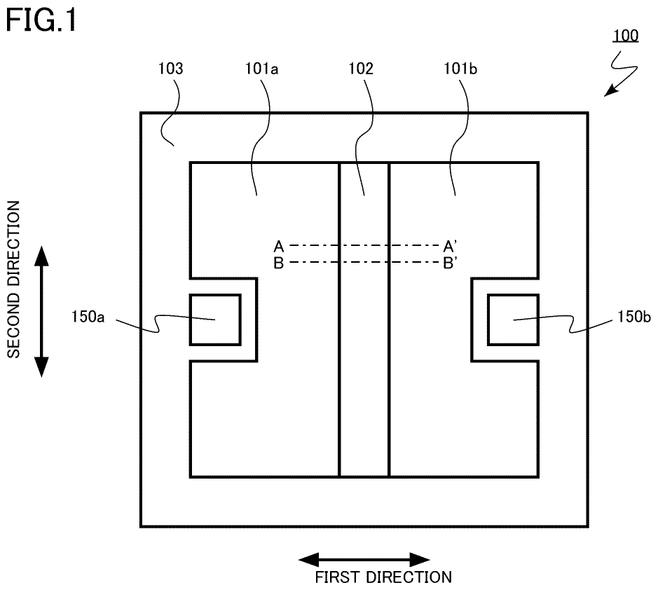

FIG. 1 is a schematic top view of the semiconductor device according to the first embodiment. FIG. 1 is a layout diagram of the semiconductor device according to the first embodiment. FIG. 1 shows a layout pattern of a first element region, a second element region, an intermediate region, a termination region, a first gate electrode pad, and a second gate electrode pad.

The semiconductor device according to the first embodiment is a bidirectional switching device 100 using silicon carbide. The bidirectional switching device 100 has a structure in which two planar gate type vertical MOSFETs are connected to each other with their drain electrodes in common. The bidirectional switching device 100 is a bidirectional switching device in which two planar gate type vertical MOSFETs are integrated into one chip. In addition, each of the two planar gate type vertical MOSFETs includes a Schottky Barrier Diode (SBD) as a built-in diode.

Hereinafter, a case where the first conductive type is n-type and the second conductive type is p-type will be described as an example. Each MOSFET included in the bidirectional switching device 100 according to the first embodiment is a vertical n-channel MOSFET having electrons as carriers.

The bidirectional switching device 100 includes a first element region 101a, a second element region 101b, an intermediate region 102, and a termination region 103.

The intermediate region 102 is provided between the first element region 101a and the second element region 101b. The termination region 103 surrounds the first element region 101a, the second element region 101b, and the intermediate region 102.

The first element region 101a includes a plurality of MOSFETs and a plurality of SBDs. The second element region 101b includes a plurality of MOSFETs and a plurality of SBDs.

The intermediate region 102 and the termination region 103 reduce the strength of the electric field applied to the termination end of the first element region 101a or the second element region 101b when the bidirectional switching device 100 is in an off state. The intermediate region 102 and the termination region 103 have a function of increasing the dielectric breakdown voltage of the bidirectional switching device 100. In particular, the intermediate region 102 reduces the strength of the electric field applied between the first element region 101a and the second element region 101b.

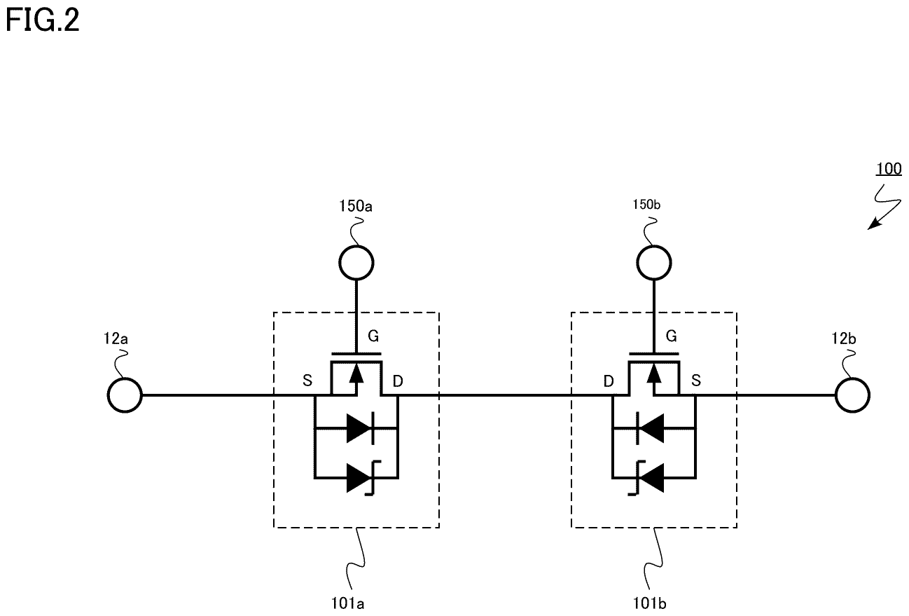

FIG. 2 is an equivalent circuit diagram of the semiconductor device according to the first embodiment.

As shown in FIG. 2, the drain of a MOSFET in the first element region 101a is connected to the drain of a MOSFET in the second element region 101b. The source of the MOSFET in the first element region 101a is connected to a first source electrode 12a. The source of the MOSFET in the second element region 101b is connected to a second source electrode 12b. The gate electrode of the MOSFET in the first element region 101a is connected to a first gate electrode pad 150a. The gate electrode of the MOSFET in the second element region 101b is connected to a second gate electrode pad 150b.

The MOSFET in the first element region 101a and the MOSFET in the second element region 101b each include a pn junction diode and an SBD as built-in diodes.

In the MOSFET in the first element region 101a and the MOSFET in the second element region 101b, a current can be made to flow using the built-in diodes even when the MOSFETs are in an off state. In the MOSFET in the first element region 101a and the MOSFET in the second element region 101b, in particular, an SBD that operates in a unipolar manner is provided as a built-in diode. By providing the SBD that operates in a unipolar manner, it is possible to reduce the current loss in the low current region when a current is made to flow using a built-in diode and to suppress the growth of stacked defect in the silicon carbide layer.

In addition, the MOSFET in the first element region 101a and the MOSFET in the second element region 101b have a superjunction structure (hereinafter, referred to as an “SJ structure”). The SJ structure is a structure in which a p-type semiconductor region and an n-type semiconductor region are arranged alternately. A high breakdown voltage for the MOSFET is achieved by depleting the p-type semiconductor region and the n-type semiconductor region. At the same time, a low on-resistance of the MOSFET can be achieved by making a current flow through the high impurity concentration region.

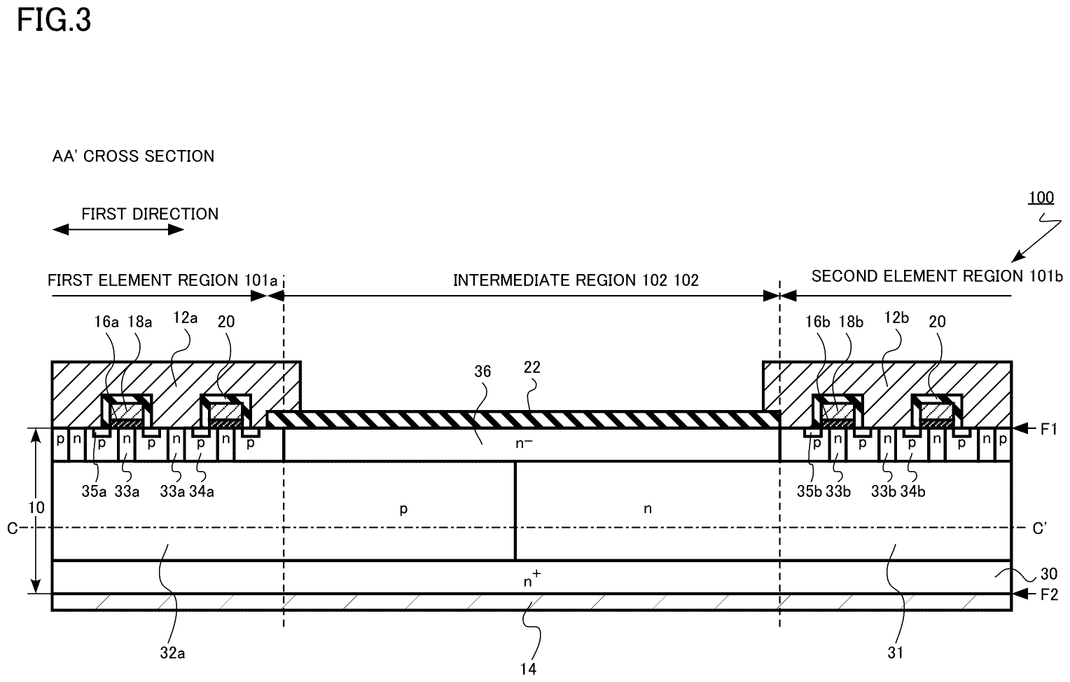

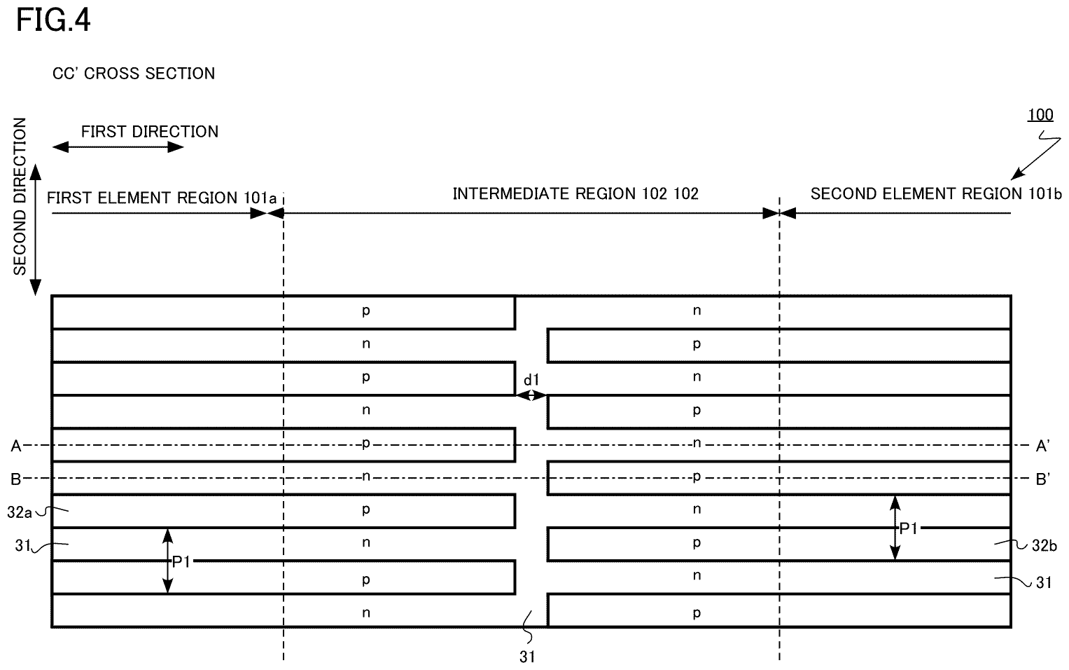

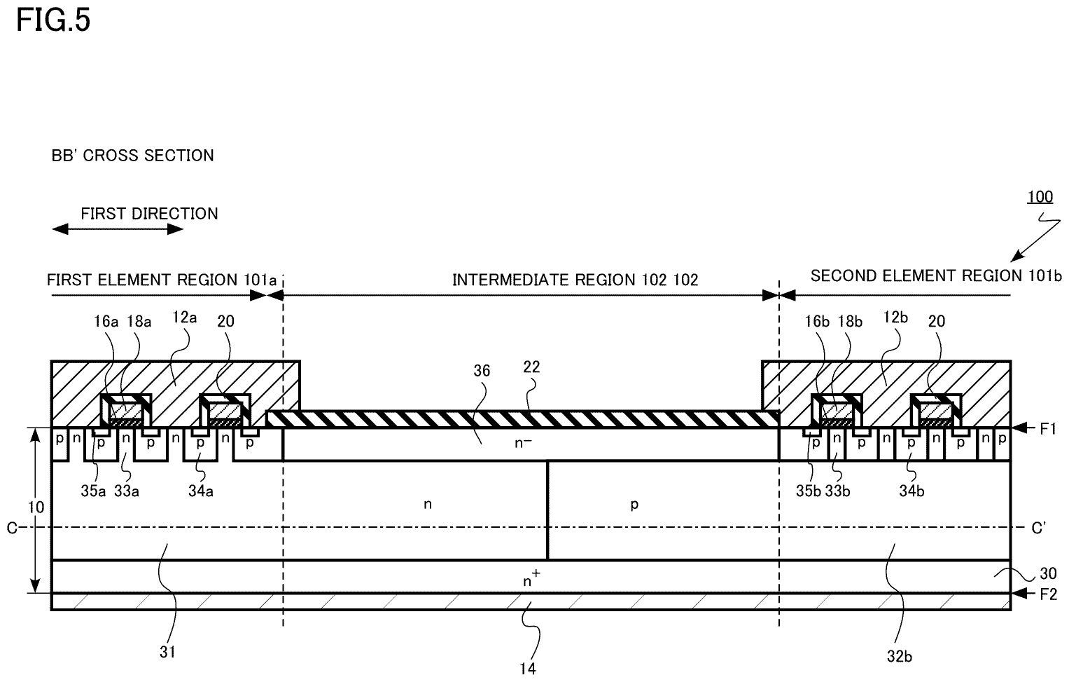

FIG. 3 is a schematic cross-sectional view of the semiconductor device according to the first embodiment. FIG. 3 is a cross-sectional view taken along the line AA′ of FIGS. 1 and 4. FIG. 4 is a schematic cross-sectional view of the semiconductor device according to the first embodiment. FIG. 4 is a cross-sectional view taken along the line CC′ of FIGS. 3 and 5. FIG. 5 is a schematic cross-sectional view of the semiconductor device according to the first embodiment. FIG. 5 is a cross-sectional view taken along the line BB′ of FIGS. 1 and 4.

The bidirectional switching device 100 includes a silicon carbide layer 10, a first source electrode 12a (first electrode), a second source electrode 12b (second electrode), a back surface metal layer 14, a first gate insulating layer 16a, a second gate insulating layer 16b, a first gate electrode 18a, a second gate electrode 18b, an interlayer insulating layer 20, a field insulating layer 22, a first gate electrode pad 150a, and a second gate electrode pad 150b.

The silicon carbide layer 10 includes an n⁺-type back surface region 30 (first silicon carbide region), an n-type drift region 31 (second silicon carbide region), a p-type first pillar region 32a (third silicon carbide region), a p-type second pillar region 32b (seventh silicon carbide region), an n-type first JFET region 33a (fourth silicon carbide region), an n-type second JFET region 33b (eighth silicon carbide region), a p-type first base region 34a (fifth silicon carbide region), a p-type second base region 34b (ninth silicon carbide region), an n⁺-type first source region 35a (sixth silicon carbide region), an n⁺-type second source region 35b (tenth silicon carbide region), and an n⁻-type surface region 36 (eleventh silicon carbide region).

The first element region 101a includes the silicon carbide layer 10, the first source electrode 12a (first electrode), the back surface metal layer 14, the first gate insulating layer 16a, the first gate electrode 18a, and the interlayer insulating layer 20.

The silicon carbide layer 10 in the first element region 101a includes the n⁺-type back surface region 30 (first silicon carbide region), the n-type drift region 31 (second silicon carbide region), the p-type first pillar region 32a (third silicon carbide region), the n-type first JFET region 33a (fourth silicon carbide region), the p-type first base region 34a (fifth silicon carbide region), and the n⁺-type first source region 35a (sixth silicon carbide region).

The silicon carbide layer 10 is provided between the first source electrode 12a and the back surface metal layer 14. The silicon carbide layer 10 is a single crystal SiC. The silicon carbide layer 10 is, for example, 4H—SiC.

The silicon carbide layer 10 has a first face (“F1” in FIG. 3) and a second face (“F2” in FIG. 3). The first face F1 is the surface of the silicon carbide layer. In addition, the second face F2 is the back surface of the silicon carbide layer. Hereinafter, the first face F1 may be referred to as a surface, and the second face F2 may be referred to as a back surface. The first face F1 is disposed on the first source electrode 12a side of the silicon carbide layer 10. In addition, the second face F2 is disposed on the back surface metal layer 14 side of the silicon carbide layer 10. The first face F1 and the second face F2 face each other. In addition, “face” of the first face F1 and the second face F2 indicates, for example, an interface between a silicon carbide layer and an insulating film or between a silicon carbide layer and a metal.

The first face is parallel to the first and second directions. The second direction is perpendicular to the first direction.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The thickness of the silicon carbide layer 10 is, for example, equal to or more than 5 μm and equal to or less than 350 μm.

The n⁺-type back surface region 30 is in contact with the second face F2.

The back surface region 30 contains, for example, nitrogen (N) as an n-type impurity. The n-type impurity concentration in the back surface region 30 is, for example, equal to or more than 5×10¹⁹ cm⁻³ and equal to or less than 1×10²¹ cm⁻³.

The back surface region 30 functions as, for example, a current path between the first element region 101a and the second element region 101b.

The n-type drift region 31 is provided between the back surface region 30 and the first face F1. The drift region 31 is in contact with, for example, the back surface region 30.

The drift region 31 contains, for example, nitrogen (N) as an n-type impurity. The n-type impurity concentration in the drift region 31 is lower than the n-type impurity concentration in the back surface region 30. The n-type impurity concentration in the drift region 31 is equal to or more than 1×10¹⁶ cm⁻3 and equal to or less than 1×10¹⁸ cm⁻³, for example. The thickness of the drift region 31 is, for example, equal to or more than 3 μm and equal to or less than 100 μm.

The drift region 31 functions as, for example, a current path when the MOSFET is turned on. In addition, the drift region 31 functions as a current path when the SBD is turned on. In addition, the drift region 31 functions as a part of the SJ structure.

The p-type first pillar region 32a is provided between the back surface region 30 and the first face F1. The first pillar region 32a is in contact with, for example, the back surface region 30.

A plurality of first pillar regions 32a extend in the first direction. The plurality of first pillar regions 32a are repeatedly arranged in the second direction with the drift region 31 interposed therebetween. The plurality of first pillar regions 32a are repeatedly arranged in the second direction with a first period (P1 in FIG. 4).

The first pillar region 32a contains, for example, aluminum (Al) as a p-type impurity. The p-type impurity concentration in the first pillar region 32a is, for example, equal to or more than 1×10¹⁶ cm⁻³ and equal to or less than 1×10¹⁸ cm⁻³.

The first pillar region 32a is electrically connected to the first source electrode 12a. The first pillar region 32a is fixed to the electric potential of the first source electrode 12a.

The first pillar region 32a and the drift region 31 arranged alternately in the second direction form an SJ structure.

The n-type first JFET region 33a is provided between the drift region 31 and the first face F1. The first JFET region 33a is in contact with the drift region 31. The first JFET region 33a is in contact with the first face F1. For example, the first JFET region 33a is interposed between two first base regions 34a in the first direction.

The first JFET region 33a contains, for example, nitrogen (N) as an n-type impurity. The n-type impurity concentration in the first JFET region 33a is, for example, equal to or more than 1×10¹⁶ cm⁻³ and equal to or less than 1×10¹⁸ cm⁻³.

The first JFET region 33a functions as a current path when the MOSFET is turned on. In addition, the first JFET region 33a functions as a current path when the SBD is turned on.

The p-type first base region 34a is provided between the first pillar region 32a and the first face F1. The first base region 34a is in contact with the first face F1. The first base region 34a is in contact with the first pillar region 32a.

The first base region 34a extends, for example, in the second direction. For example, a plurality of first base regions 34a are repeatedly arranged in the first direction.

The first base region 34a contains, for example, aluminum (Al) as a p-type impurity. The p-type impurity concentration in the first base region 34a is, for example, equal to or more than 5×10¹⁶ cm⁻³ and equal to or less than 5×10¹⁹ cm⁻³.

The first base region 34a functions as a channel region of the MOSFET.

The n⁺-type first source region 35a is provided between the first base region 34a and the first face F1. The first source region 35a is in contact with the first face F1. The first source region 35a extends, for example, in the second direction.

The first source region 35a contains, for example, phosphorus (P) or nitrogen (N) as an n-type impurity. The n-type impurity concentration in the first source region 35a is higher than the n-type impurity concentration in the first JFET region 33a.

The n-type impurity concentration in the first source region 35a is, for example, equal to or more than 1×10¹⁹ cm⁻³ and equal to or less than 1×10²⁰ cm⁻³.

The first gate electrode 18a is provided on the first face F1 side of the silicon carbide layer 10. The first gate electrode 18a extends, for example, in the second direction. A plurality of first gate electrodes 18a are arranged, for example, in parallel to each other in the first direction. The first gate electrode 18a has, for example, a striped shape.

The first gate electrode 18a is a conductive layer. The first gate electrode 18a is, for example, polycrystalline silicon containing p-type or n-type impurities.

The first gate electrode 18a faces the first JFET region 33a. The first gate electrode 18a faces the first base region 34a.

The first gate electrode 18a is electrically connected to the first gate electrode pad 150a.

The first gate insulating layer 16a is provided between the first gate electrode 18a and the first JFET region 33a. The first gate insulating layer 16a is provided between the first gate electrode 18a and the first base region 34a.

The first gate insulating layer 16a is, for example, a silicon oxide.

The interlayer insulating layer 20 is provided on the first gate electrode 18a and the silicon carbide layer 10. The interlayer insulating layer 20 is, for example, a silicon oxide.

The first source electrode 12a is provided on the first face F1 side of the silicon carbide layer 10 in the first element region 101a. The first source electrode 12a is provided on the interlayer insulating layer 20.

The first source electrode 12a is in contact with the silicon carbide layer 10. The first source electrode 12a is in contact with the first source region 35a. The first source electrode 12a is in contact with the first JFET region 33a.

The contact between the first source electrode 12a and the first source region 35a is, for example, an ohmic contact. The contact between the first source electrode 12a and the first JFET region 33a is, for example, a Schottky contact.

The back surface metal layer 14 is in contact with the second face F2. The back surface metal layer 14 is in contact with the back surface region 30. The back surface metal layer 14 functions as, for example, a current path between the first element region 101a and the second element region 101b.

The second element region 101b has a similar structure to the first element region 101a.

The second element region 101b includes the silicon carbide layer 10, the second source electrode 12b (second electrode), the back surface metal layer 14, a second gate insulating layer 16b, the second gate electrode 18b, and the interlayer insulating layer 20.

The silicon carbide layer 10 in the second element region 101b includes the n⁺-type back surface region 30 (first silicon carbide region), the n-type drift region 31 (second silicon carbide region), the p-type second pillar region 32b (seventh silicon carbide region), the n-type second JFET region 33b (eighth silicon carbide region), the p-type second base region 34b (ninth silicon carbide region), and the n⁺-type second source region 35b (tenth silicon carbide region).

The p-type second pillar region 32b is provided between the back surface region 30 and the first face F1. The second pillar region 32b is in contact with, for example, the back surface region 30.

A plurality of second pillar regions 32b extend in the first direction. The plurality of second pillar regions 32b are repeatedly arranged in the second direction with the drift region 31 interposed therebetween. The plurality of second pillar regions 32b are repeatedly arranged in the second direction with the same first period (P1 in FIG. 4) as for the first pillar regions 32a.

The second pillar region 32b contains, for example, aluminum (Al) as a p-type impurity. The p-type impurity concentration in the second pillar region 32b is, for example, equal to or more than 1×10¹⁶ cm⁻³ and equal to or less than 1×10¹⁹ cm⁻³.

The second pillar region 32b is electrically connected to the second source electrode 12b. The second pillar region 32b is fixed to the electric potential of the second source electrode 12b.

The second pillar regions 32b and the drift region 31 arranged alternately in the second direction form an SJ structure.

The n-type second JFET region 33b is provided between the drift region 31 and the first face F1. The second JFET region 33b is in contact with the drift region 31. The second JFET region 33b is in contact with the first face F1. For example, the second JFET region 33b is interposed between two second base regions 34b in the first direction.

The second JFET region 33b contains, for example, nitrogen (N) as an n-type impurity. The n-type impurity concentration in the second JFET region 33b is, for example, equal to or more than 1×10¹⁶ cm⁻³ and equal to or less than 1×10¹⁸ cm⁻³.

The second JFET region 33b functions as a current path when the MOSFET is turned on. In addition, the second JFET region 33b functions as a current path when the SBD is turned on.

The p-type second base region 34b is provided between the second pillar region 32b and the first face F1. The second pillar region 32b is in contact with the first face F1. The second pillar region 32b is in contact with the first pillar region 32a.

The second base region 34b extends, for example, in the second direction. For example, a plurality of second base regions 34b are repeatedly arranged in the second direction.

The second base region 34b contains, for example, aluminum (Al) as a p-type impurity. The p-type impurity concentration in the second base region 34b is, for example, equal to or more than 5×10¹⁶ cm⁻³ and equal to or less than 5×10¹⁹ cm⁻³.

The second base region 34b functions as a channel region of the MOSFET.

The n⁺-type second source region 35b is provided between the second base region 34b and the first face F1. The second source region 35b is in contact with the first face F1. The second source region 35b extends, for example, in the second direction.

The second source region 35b contains, for example, phosphorus (P) or nitrogen (N) as an n-type impurity. The n-type impurity concentration in the second source region 35b is higher than the n-type impurity concentration in the second JFET region 33b.

The n-type impurity concentration in the second source region 35b is, for example, equal to or more than 1×10¹⁹ cm⁻³ and equal to or less than 1×10²⁰ cm⁻³.

The second gate electrode 18b is provided on the first face F1 side of the silicon carbide layer 10. The second gate electrode 18b extends, for example, in the second direction. A plurality of second gate electrodes 18b are arranged, for example, in parallel to each other in the first direction. The second gate electrode 18b has, for example, a striped shape.

The second gate electrode 18b faces the second JFET region 33b. The second gate electrode 18b faces the second base region 34b.

The second gate electrode 18b is electrically connected to a second gate electrode pad 150b.

The second gate insulating layer 16b is provided between the second gate electrode 18b and the second JFET region 33b. The second gate insulating layer 16b is provided between the second gate electrode 18b and the second base region 34b.

The interlayer insulating layer 20 is provided on the second gate electrode 18b and the silicon carbide layer 10.

The second source electrode 12b is provided on the first face F1 side of the silicon carbide layer 10 in the second element region 101b. The second source electrode 12b is provided on the interlayer insulating layer 20. The second source electrode 12b is physically and electrically separated from the first source electrode 12a.

The second source electrode 12b is in contact with the silicon carbide layer 10. The second source electrode 12b is in contact with the second source region 35b. The second source electrode 12b is in contact with the second JFET region 33b.

The contact between the second source electrode 12b and the second source region 35b is, for example, an ohmic contact. The contact between the second source electrode 12b and the second JFET region 33b is, for example, a Schottky contact.

The intermediate region 102 includes the silicon carbide layer 10 and a field insulating layer 22.

The silicon carbide layer 10 in the intermediate region 102 includes the n⁺-type back surface region 30 (first silicon carbide region), the n-type drift region 31 (second silicon carbide region), the p-type first pillar region 32a (third silicon carbide region), the p-type second pillar region 32b (seventh silicon carbide region), and the n⁻-type surface region 36 (eleventh silicon carbide region).

In the intermediate region 102, a plurality of first pillar regions 32a are repeatedly arranged in the second direction with the drift region 31 interposed therebetween, as in the first element region 101a. The plurality of first pillar regions 32a are repeatedly arranged in the second direction with the first period (P1 in FIG. 4).

In the intermediate region 102, the plurality of second pillar regions 32b are repeatedly arranged in the second direction with the drift region 31 interposed therebetween, as in the second element region 101b. The plurality of second pillar regions 32b are repeatedly arranged in the second direction with the first period (P1 in FIG. 4).

As shown in FIG. 4, in the intermediate region 102, the arrangement of the plurality of second pillar regions 32b in the second direction is shifted by half the first period P1 with respect to the arrangement of the plurality of first pillar regions 32a in the second direction.

In the intermediate region 102, as shown in FIG. 4, in a cross section parallel to the first face F1, the shortest distance (d1 in FIG. 4) between the first pillar region 32a and the second pillar region 32b is, for example, equal to or less than the first period P1.

The n⁻-type surface region 36 is provided between the first pillar region 32a and the first face F1. The surface region 36 is provided between the second pillar region 32b and the first face F1. The surface region 36 is in contact with, for example, the first face F1.

Since the surface region 36 is provided, the first pillar region 32a and the first face F1 are spaced apart from each other. In addition, since the surface region 36 is provided, the second pillar region 32b and the first face F1 are spaced apart from each other.

The surface region 36 contains, for example, nitrogen (N) as an n-type impurity. The n-type impurity concentration in the surface region 36 is, for example, lower than the n-type impurity concentration in the drift region 31. The n-type impurity concentration in the surface region 36 is, for example, lower than the n-type impurity concentration in the first JFET region 33a and the n-type impurity concentration in the second JFET region 33b. The n-type impurity concentration in the surface region 36 is, for example, equal to or more than 1×10¹⁵ cm⁻³ and equal to or less than 1×10¹⁸ cm⁻³.

The field insulating layer 22 is provided on the first face F1 of the silicon carbide layer 10. The field insulating layer 22 is in contact with the surface region 36. The field insulating layer 22 is, for example, a silicon oxide.

Next, the function and effect of the semiconductor device according to the first embodiment will be described.

The intermediate region 102 reduces the strength of the electric field applied between the first element region 101a and the second element region 101b. By reducing the strength of the electric field, the dielectric breakdown voltage of the bidirectional switching device is increased. From the viewpoint of realizing the miniaturization of the bidirectional switching device by reducing the area occupied by the intermediate region 102 in the chip, it is desirable to shorten the length of the intermediate region 102 in the first direction.

In the bidirectional switching device 100 according to the first embodiment, an SJ structure extending from both the first element region 101a and the second element region 101b is formed in the intermediate region 102. By providing the SJ structure, the strength of the electric field in the intermediate region 102 is effectively reduced compared with a case where the SJ structure is not provided. Therefore, the length of the intermediate region 102 in the first direction can be shortened.

In addition, in the bidirectional switching device 100 according to the first embodiment, in the intermediate region 102, the arrangement of the plurality of second pillar regions 32b in the second direction is shifted by half the first period P1 with respect to the arrangement of the plurality of first pillar regions 32a in the second direction. In other words, an SJ structure extending from the first element region 101a and an SJ structure extending from the second element region 101b are provided so as to be shifted from each other by a half period in the second direction. With this arrangement, the strength of the electric field in the intermediate region 102 is more effectively reduced. As a result, the length of the intermediate region 102 in the first direction can be shortened compared with a case where the SJ structure is not shifted by half a period.

In the bidirectional switching device 100 according to the first embodiment, the first pillar region 32a is spaced apart from the first face F1 by providing the surface region 36. In addition, the second pillar region 32b is spaced apart from the first face F1 by providing the surface region 36.

If a pn junction is provided on the surface of the silicon carbide layer 10 in the intermediate region 102, when an electric field is applied between the first element region 101a and the second element region 101b, for example, holes may be injected into the field insulating layer 22 or movable ions may move into the field insulating layer 22 due to the electric field distribution generated at the pn junction directly below the field insulating layer 22. In this case, for example, there may be a portion where the electric field strength is locally high, which may reduce the dielectric breakdown voltage of the bidirectional switching device.

The above-described effect of the pn junction directly below the field insulating layer 22 is particularly noticeable in devices using silicon carbide to which a high electric field is applied.

In the bidirectional switching device 100 according to the first embodiment, the first pillar region 32a is spaced apart from the first face F1 by providing the surface region 36. In addition, the second pillar region 32b is spaced apart from the first face F1 by providing the surface region 36. Therefore, the pn junction of the SJ structure is not in contact with the area directly below the field insulating layer 22 in the intermediate region 102. As a result, the decrease in the dielectric breakdown voltage is suppressed.

From the viewpoint of increasing the dielectric breakdown voltage of the bidirectional switching device 100, it is preferable that the n-type impurity concentration in the surface region 36 is low, particularly in devices using silicon carbide to which a high electric field is applied. From the viewpoint of increasing the dielectric breakdown voltage of the bidirectional switching device 100, it is preferable that the n-type impurity concentration in the surface region 36 is lower than the n-type impurity concentration in the drift region 31. In addition, from the viewpoint of increasing the dielectric breakdown voltage of the bidirectional switching device 100, it is preferable that the n-type impurity concentration in the surface region 36 is lower than the n-type impurity concentration in the first JFET region 33a and the n-type impurity concentration in the second JFET region 33b.

From the viewpoint of shortening the length of the bidirectional switching device 100 in the first direction in the intermediate region 102, it is preferable that, in a cross section parallel to the first face F1 in the intermediate region 102, the shortest distance (d1 in FIG. 4) between the first pillar region 32a and the second pillar region 32b is equal to or less than the first period P1.

### Modification Example

A semiconductor device according to a modification example of the first embodiment is different from the semiconductor device according to the first embodiment in that the silicon carbide layer in the intermediate region further includes a twelfth silicon carbide region of a second conductive type, which is spaced apart from the third silicon carbide region and the seventh silicon carbide region in the first direction, extends in the second direction, and is provided between the third silicon carbide region and the seventh silicon carbide region, in the second silicon carbide region.

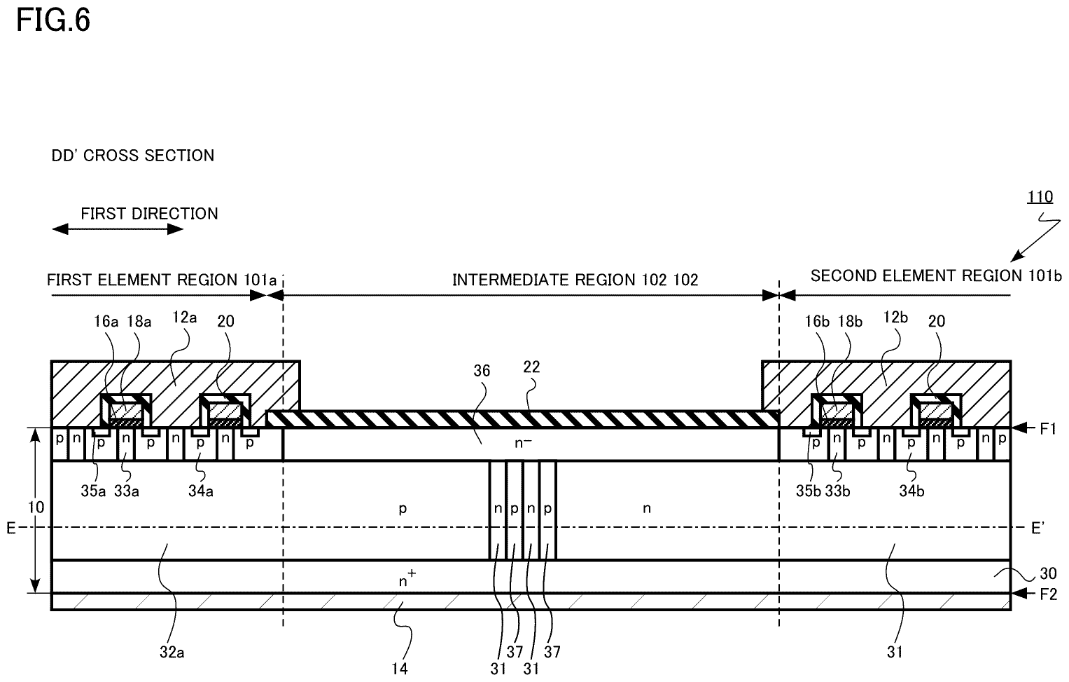

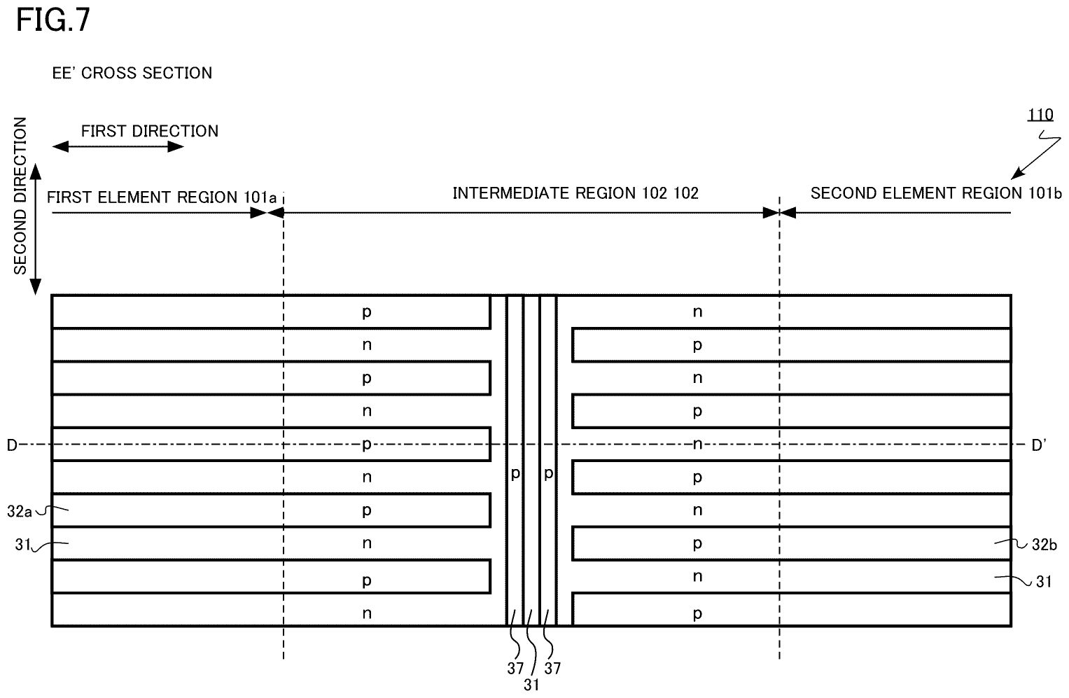

FIG. 6 is a schematic cross-sectional view of a semiconductor device according to a modification example of the first embodiment. FIG. 6 is a cross-sectional view taken along the line DD′ of FIG. 7. FIG. 7 is a schematic cross-sectional view of the semiconductor device according to the modification example of the first embodiment. FIG. 7 is a cross-sectional view taken along the line EE′ of FIG. 6.

FIG. 6 is a diagram corresponding to FIG. 3 in the first embodiment. FIG. 7 is a diagram corresponding to FIG. 4 in the first embodiment.

The semiconductor device according to the modification example of the first embodiment is a bidirectional switching device 110.

In the bidirectional switching device 110, the silicon carbide layer 10 includes a p-type isolation region 37 (twelfth silicon carbide region) in the intermediate region 102.

The isolation region 37 is provided in the drift region 31. The isolation region 37 is spaced apart from the first pillar region 32a and the second pillar region 32b in the first direction. The isolation region 37 extends in the second direction. The isolation region 37 is provided between the first pillar region 32a and the second pillar region 32b.

The isolation region 37 is provided between the surface region 36 and the second face F2. The isolation region 37 is spaced apart from the first face F1.

The isolation region 37 contains, for example, aluminum (Al) as a p-type impurity. The p-type impurity concentration in the isolation region 37 is, for example, equal to or more than 5×10¹⁶ cm⁻³ and equal to or less than 5×10¹⁸ cm⁻³.

For example, two isolation regions 37 are provided. The number of isolation regions 37 may be, for example, one or three or more.

According to the bidirectional switching device 110 according to the modification example of the first embodiment, the strength of the electric field in the intermediate region 102 is more effectively reduced by providing the isolation region 37. Therefore, the length of the intermediate region 102 in the first direction can be further shortened.

As described above, according to the first embodiment and its modification examples, since the length of the intermediate region 102 in the first direction can be shortened, it is possible to realize a semiconductor device that can be miniaturized.

### Second Embodiment

A semiconductor device according to a second embodiment is different from the semiconductor device according to the first embodiment in that, in the intermediate region, the position of a first end portion of the third silicon carbide region in the first direction on the second element region side is closer to the second element region than the position of a second end portion of the seventh silicon carbide region in the first direction on the first element region side. Hereinafter, the description of a part of the content overlapping the first embodiment may be omitted.

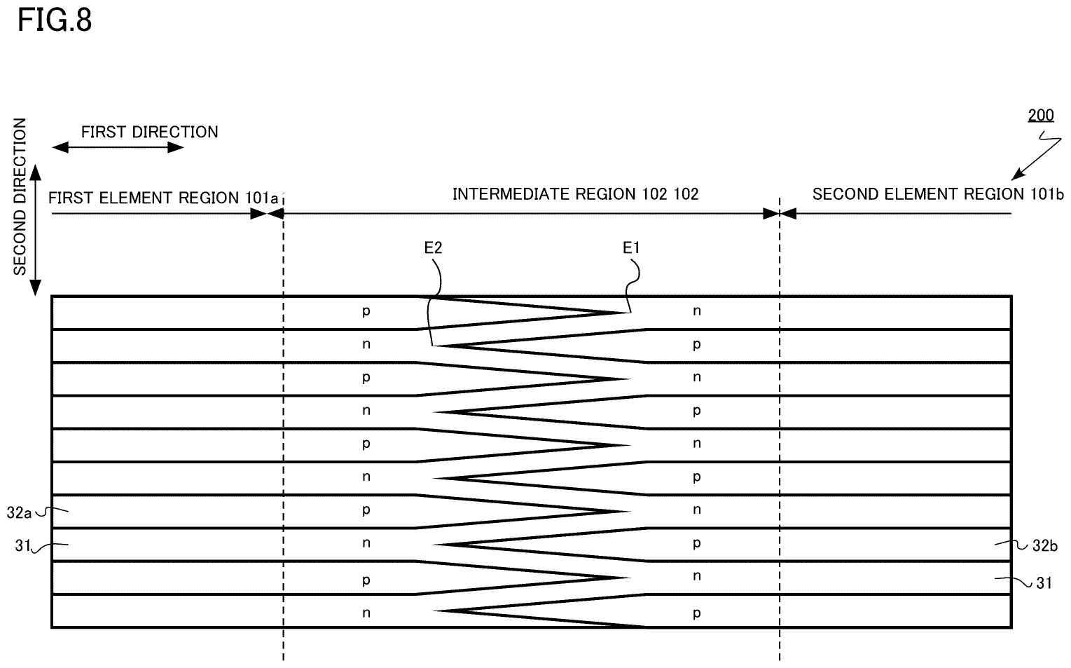

FIG. 8 is a schematic cross-sectional view of the semiconductor device according to the second embodiment. FIG. 8 is a diagram corresponding to FIG. 4 in the first embodiment.

The semiconductor device according to the second embodiment is a bidirectional switching device 200.

In the intermediate region 102 of the bidirectional switching device 200, the position of a first end portion (E1 in FIG. 8) of the first pillar region 32a in the first direction on the second element region 101b side is closer to the second element region 101b than the position of a second end portion (E2 in FIG. 8) of the second pillar region 32b in the first direction on the first element region 101a side.

In the intermediate region 102, the second pillar region 32b is provided in the second direction of the first pillar region 32a. The positions of the first pillar region 32a and the second pillar region 32b overlap each other in the first direction.

The width of the first pillar region 32a in the second direction decreases toward the first end portion E1, for example. The width of second pillar region 32b in the second direction decreases toward the second end portion E2, for example.

According to the bidirectional switching device 200 according to the second embodiment, since the positions of the first pillar region 32a and the second pillar region 32b overlap each other in the first direction, it is possible to further shorten the length of the intermediate region 102 in the first direction.

### Modification Example

A semiconductor device according to a modification example of the second embodiment is different from the semiconductor device according to the second embodiment in that the silicon carbide layer in the intermediate region further includes a thirteenth silicon carbide region that is provided between the third silicon carbide region and the seventh silicon carbide region in the second direction and has a first conductive type impurity concentration lower than the first conductive type impurity concentration in the second silicon carbide region.

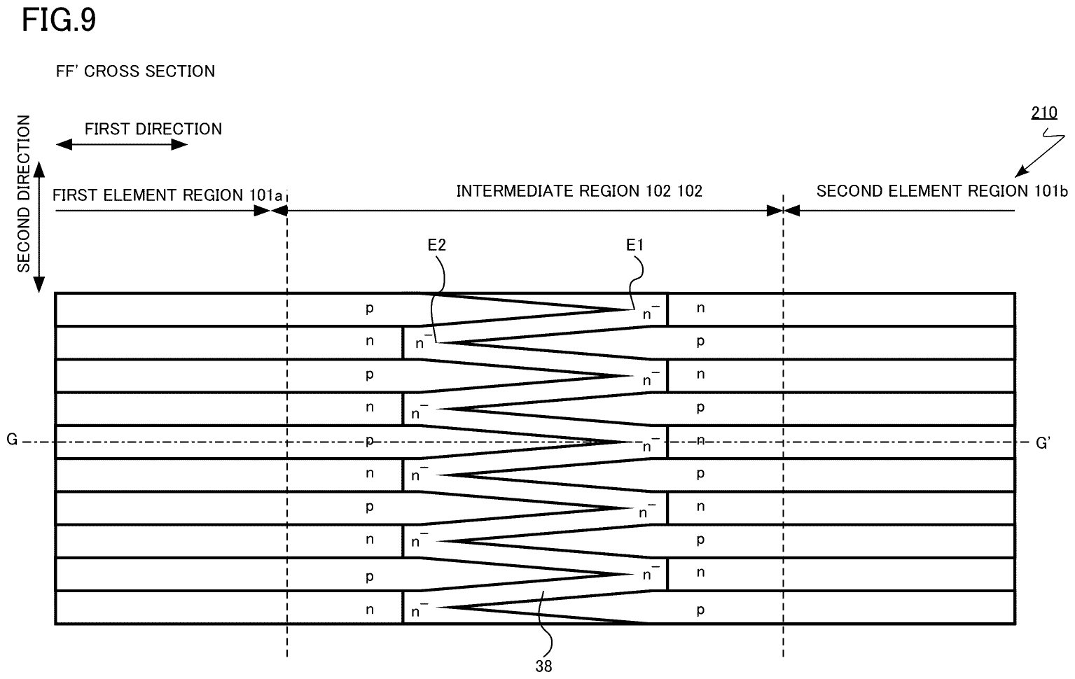

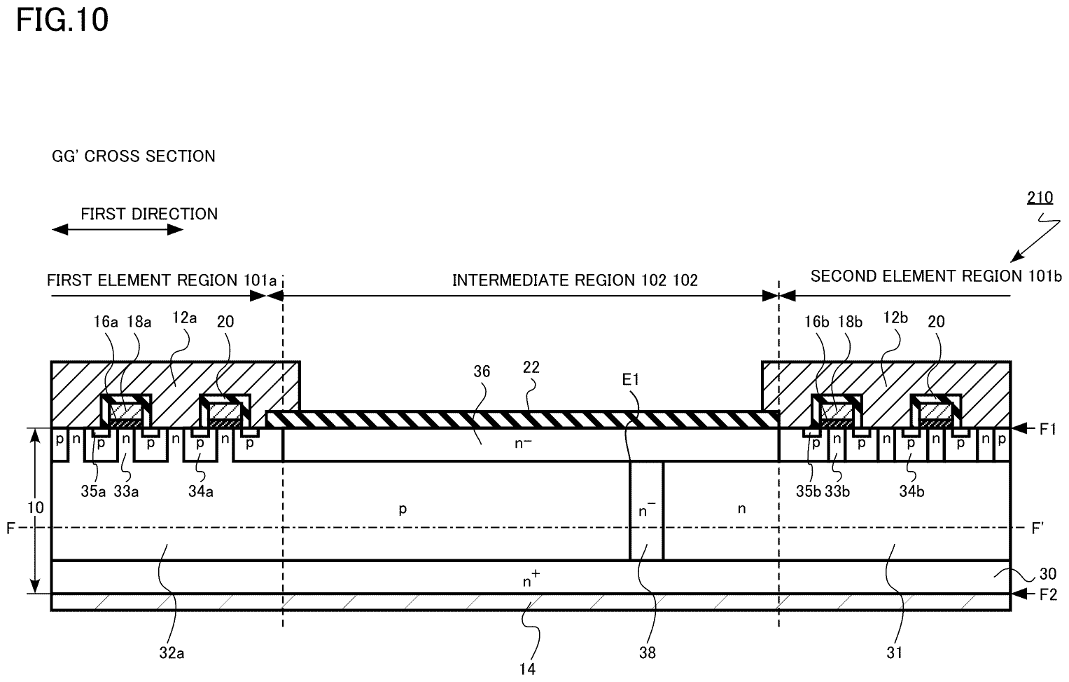

FIG. 9 is a schematic cross-sectional view of a semiconductor device according to a modification example of the second embodiment. FIG. 9 is a cross-sectional view taken along the line FF′ of FIG. 10. FIG. 10 is a schematic cross-sectional view of the semiconductor device according to the modification example of the second embodiment. FIG. 10 is a cross-sectional view taken along the line GG′ of FIG. 9.

FIG. 9 is a diagram corresponding to FIG. 8 in the second embodiment.

The semiconductor device according to the modification example of the second embodiment is a bidirectional switching device 210.

In the bidirectional switching device 210, the silicon carbide layer 10 includes an n⁻-type low concentration region 38 (thirteenth silicon carbide region) in the intermediate region 102.

The low concentration region 38 is provided between the first pillar region 32a and the second pillar region 32b in the second direction. For example, a first end portion E1 (E1 in FIG. 9) of the first pillar region 32a in the first direction on the second element region 101b side and a second end portion (E2 in FIG. 9) of the second pillar region 32b in the first direction on the first element region 101a side are provided in the low concentration region 38.

The low concentration region 38 contains, for example, nitrogen (N) as an n-type impurity. The n-type impurity concentration in the low concentration region 38 is lower than the n-type impurity concentration in the drift region 31. The n-type impurity concentration in the low concentration region 38 is, for example, equal to or more than 1×10¹⁵ cm⁻³ and equal to or less than 5×10¹⁷ cm⁻³.

According to the bidirectional switching device 210 according to the modification example of the second embodiment, since the low concentration region 38 is provided, the strength of the electric field in the intermediate region 102 is effectively reduced. Therefore, it is possible to further shorten the length of the intermediate region 102 in the first direction.

As described above, according to the second embodiment and its modification example, since the length of the intermediate region 102 in the first direction can be shortened, it is possible to realize a semiconductor device that can be miniaturized.

In the first and second embodiments, the case where the first conductive type is n-type and the second conductive type is p-type has been described as an example. However, the first conductive type can be p-type and the second conductive type can be n-type.

In the first and second embodiments, aluminum (Al) is exemplified as a p-type impurity, but boron (B) can also be used. In addition, although nitrogen (N) and phosphorus (P) are exemplified as n-type impurities, arsenic (As), antimony (Sb), and the like can also be applied.

In the first and second embodiments, the case where the gate electrode has a striped shape extending in the second direction in the element region has been described as an example. However, for example, it is also possible to adopt a structure in which the gate electrode has a striped shape extending in the first direction. In addition, for example, it is also possible to adopt a structure in which the gate electrode has a mesh shape.

In the first and second embodiments, the case where the widths of the p-type pillar region and the n-type drift region in the second direction are the same has been described as an example. However, the widths of the p-type pillar region and the n-type drift region in the second direction may be different.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first element region;
a second element region; and
an intermediate region provided between the first element region and the second element region,
wherein the first element region includes:
a silicon carbide layer having a first face and a second face on a side opposite to the first face and including:
a first silicon carbide region of a first conductive type in contact with the second face;
a second silicon carbide region of the first conductive type provided between the first silicon carbide region and the first face and having a first conductive type impurity concentration lower than a first conductive type impurity concentration in the first silicon carbide region;
a plurality of third silicon carbide regions of a second conductive type provided between the first silicon carbide region and the first face, extending in a first direction parallel to the first face, and repeatedly arranged with a first period with the second silicon carbide region interposed therebetween in a second direction parallel to the first face and perpendicular to the first direction;
a fourth silicon carbide region of the first conductive type provided between the second silicon carbide region and the first face and in contact with the second silicon carbide region;
a fifth silicon carbide region of the second conductive type provided between the third silicon carbide region and the first face and in contact with the third silicon carbide region; and
a sixth silicon carbide region of the first conductive type provided between the third silicon carbide region and the first face;
a first gate electrode facing the fourth silicon carbide region and the fifth silicon carbide region;
a first gate insulating layer provided between the first gate electrode and the fourth silicon carbide region and between the first gate electrode and the fifth silicon carbide region; and
a first electrode provided on the first face side of the silicon carbide layer, in contact with the fourth silicon carbide region and the sixth silicon carbide region, and electrically connected to the fifth silicon carbide region,
the second element region includes:
the silicon carbide layer including:
the first silicon carbide region;
the second silicon carbide region;
a plurality of seventh silicon carbide regions of the second conductive type provided between the first silicon carbide region and the first face, extending in the first direction, and repeatedly arranged with the first period with the second silicon carbide region interposed therebetween in the second direction;
an eighth silicon carbide region of the first conductive type provided between the second silicon carbide region and the first face and in contact with the second silicon carbide region;
a ninth silicon carbide region of the second conductive type provided between the seventh silicon carbide region and the first face and in contact with the seventh silicon carbide region; and
a tenth silicon carbide region of the first conductive type provided between the ninth silicon carbide region and the first face;
a second gate electrode facing the eighth silicon carbide region and the ninth silicon carbide region;
a second gate insulating layer provided between the second gate electrode and the eighth silicon carbide region and between the second gate electrode and the ninth silicon carbide region; and
a second electrode provided on the first face side of the silicon carbide layer, in contact with the eighth silicon carbide region and the tenth silicon carbide region, electrically connected to the ninth silicon carbide region, and electrically isolated from the first electrode,
the intermediate region includes:
the silicon carbide layer including:
the first silicon carbide region;
the second silicon carbide region;
the third silicon carbide region;
the seventh silicon carbide region; and
an eleventh silicon carbide region of the first conductive type provided between the third silicon carbide region and the first face and between the seventh silicon carbide region and the first face, and
in the intermediate region, an arrangement of the seventh silicon carbide regions in the second direction is shifted by half the first period with respect to an arrangement of the third silicon carbide regions in the second direction.

2. The semiconductor device according to claim 1,
wherein a first conductive type impurity concentration in the eleventh silicon carbide region is lower than a first conductive type impurity concentration in the second silicon carbide region.

3. The semiconductor device according to claim 1,
wherein a first conductive type impurity concentration in the eleventh silicon carbide region is lower than a first conductive type impurity concentration in the fourth silicon carbide region and a first conductive type impurity concentration in the eighth silicon carbide region.

4. The semiconductor device according to claim 1,
wherein a first conductive type impurity concentration in the eleventh silicon carbide region is equal to or more than 1×10¹⁵ cm⁻³ and equal to or less than 1×10¹⁸ cm⁻³.

5. The semiconductor device according to claim 1,
wherein the eleventh silicon carbide region is in contact with the first face F1.

6. The semiconductor device according to claim 1,
wherein, in a cross section parallel to the first face in the intermediate region, a shortest distance between the third silicon carbide region and the seventh silicon carbide region is equal to or less than the first period.

7. The semiconductor device according to claim 1,
wherein the silicon carbide layer in the intermediate region further includes, in the second silicon carbide region, a twelfth silicon carbide region of the second conductive type spaced apart from the third silicon carbide region and the seventh silicon carbide region in the first direction, extending in the second direction, and provided between the third silicon carbide region and the seventh silicon carbide region.

8. The semiconductor device according to claim 7,
wherein the twelfth silicon carbide region is spaced apart from the first face.

9. The semiconductor device according to claim 7,
wherein the twelfth silicon carbide region is provided between the eleventh silicon carbide region and the second face.

10. The semiconductor device according to claim 7,
wherein a first conductive type impurity concentration in the eleventh silicon carbide region is lower than a first conductive type impurity concentration in the second silicon carbide region.

11. The semiconductor device according to claim 7,
wherein a first conductive type impurity concentration in the eleventh silicon carbide region is lower than a first conductive type impurity concentration in the fourth silicon carbide region and a first conductive type impurity concentration in the eighth silicon carbide region.

12. The semiconductor device according to claim 7,
wherein a first conductive type impurity concentration in the eleventh silicon carbide region is equal to or more than 1×10¹⁵ cm⁻³ and equal to or less than 1×10¹⁸ cm⁻³.

13. The semiconductor device according to claim 7,
wherein the eleventh silicon carbide region is in contact with the first face F1.

14. The semiconductor device according to claim 1,
wherein, in the intermediate region, a position of a first end portion of the third silicon carbide region in the first direction on the second element region side is closer to the second element region than a position of a second end portion of the seventh silicon carbide region in the first direction on the first element region side.

15. The semiconductor device according to claim 14,
wherein a width of the third silicon carbide region in the second direction decreases toward the first end portion, and a width of the seventh silicon carbide region in the second direction decreases toward the second end portion.

16. The semiconductor device according to claim 14,
wherein the silicon carbide layer in the intermediate region further includes a thirteenth silicon carbide region provided between the third silicon carbide region and the seventh silicon carbide region in the second direction and having a first conductive type impurity concentration lower than a first conductive type impurity concentration in the second silicon carbide region.

17. The semiconductor device according to claim 14,
wherein a first conductive type impurity concentration in the eleventh silicon carbide region is lower than a first conductive type impurity concentration in the second silicon carbide region.

18. The semiconductor device according to claim 14,
wherein a first conductive type impurity concentration in the eleventh silicon carbide region is lower than a first conductive type impurity concentration in the fourth silicon carbide region and a first conductive type impurity concentration in the eighth silicon carbide region.

19. The semiconductor device according to claim 14,
wherein a first conductive type impurity concentration in the eleventh silicon carbide region is equal to or more than 1×10¹⁵ cm⁻³ and equal to or less than 1×10¹⁸ cm⁻³.

20. The semiconductor device according to claim 14,
wherein the eleventh silicon carbide region is in contact with the first face F1.
